(19) United States
(12) Patent Application Publication
(10) Pub. No.: US 2014/0197519 A1
(43) Pub. Date: Jul. 17, 2014

(54) MIM CAPACITOR AND MIM CAPACITOR FABRICATION FOR SEMICONDUCTOR DEVICES

(71) Applicant: QUALCOMM INCORPORATED, San Diego, CA (US)

(72) Inventors: Jihong Choi, San Diego, CA (US); John J. Zhu, San Diego, CA (US); PR Chidambaram, San Diego, CA (US); Bin Yang, San Diego, CA (US); Lixin Ge, San Diego, CA (US)

(73) Assignee: QUALCOMM INCORPORATED, San Diego, CA (US)

(21) Appl. No.: 13/743,388

(22) Filed: Jan. 17, 2013

(51) Int. Cl. H01L 49/02; G06F 17/50

(52) U.S. Cl. CPC H01L 28/82; G06F 17/50
USPC 257/534; 438/397; 716/103

(57) ABSTRACT

In a particular embodiment, a method of forming a metal-insulator-metal (MIM) capacitor includes removing, using a lithographic mask, a first portion of an optical planarization layer to expose a region in which the MIM capacitor is to be formed. A second portion of an insulating layer is formed on a first conductive layer that is formed on a plurality of trench surfaces within the region. The method further includes removing at least a third portion of the insulating layer according to a lift-off technique.

### I. FIELD

The present disclosure is generally related to semiconductor devices and more particularly to metal-insulator-metal (MIM) capacitors and MIM capacitor fabrication for semiconductor devices.

### II. DESCRIPTION OF RELATED ART

Advances in technology have resulted in smaller and more powerful computing devices. For example, there currently exist a variety of portable personal computing devices, including wireless computing devices, such as portable wireless telephones, personal digital assistants (PDAs), and paging devices that are small, lightweight, and easily carried by users. More specifically, portable wireless telephones, such as cellular telephones and internet protocol (IP) telephones, can communicate voice and data packets over wireless networks. Further, many such wireless telephones include other types of devices that are incorporated therein. For example, a wireless telephone can also include a digital still camera, a digital video camera, a digital recorder, and an audio file player. Also, such wireless telephones can process executable instructions, including software applications, such as a web browser application, that can be used to access the Internet. As such, these wireless telephones can include significant computing capabilities.

Electronic devices may include one or more integrated circuits that enable such computing capabilities and other functionalities. Fabricating an integrated circuit may include “front-end-of-line” (FEOL), “middle-of-line” (MOL), and “back-end-of-line” (BEOL) stages. Typically, the FEOL stage includes patterning devices upon a semiconductor substrate (e.g., forming source and drain regions of transistors of the integrated circuit). The MOL stage may include forming gate regions of the transistors and forming local interconnect layers (e.g., interconnect layers more proximate to the semiconductor substrate than other layers, such as metal interconnect layers) to connect the transistors. The BEOL stage may include forming metal interconnect layers to further connect the transistors and other devices of the integrated circuit.

### III. SUMMARY

Integrated circuits increasingly include greater numbers of devices. For example, as semiconductor processes scale down, a particular area of an integrated circuit may generally include more capacitors, which may enable smaller and more powerful electronic devices. However, fabricating such devices within an integrated circuit may be complex and may incur significant cost. As a particular example, forming a metal-insulator-metal (MIM) capacitor (e.g. a capacitive device formed using conductive and dielectric layers) can occupy significant area of the integrated circuit. In conventional integrated circuits, the MIM capacitor may include multiple “flat” layers and is typically formed using two or three masks to separately form bottom and top electrodes of the MIM capacitor. Utilizing such multiple masks may increase cost and complexity associated with forming the MIM capacitor. Alternatively, other conventional capacitors may be formed according to different techniques. For example, a metal-oxide-metal (MOM) capacitor (also known as a “vertical plate” capacitor or a “vertical natural” capacitor) may be formed in an integrated circuit. The MOM capacitor may be formed in different layers of the integrated circuit relative to the MIM capacitor and may include a different dielectric material than the MIM capacitor. However, the MOM capacitor may be too large for some applications and may include a complex plurality of inter-digitated vertical plates.

A MIM capacitor in accordance with the present disclosure may be formed utilizing a single-mask technique. Utilizing the single-mask technique may reduce cost and complexity as compared with multiple-mask techniques. The single-mask technique may be used in connection with a lift-off technique that removes a portion of a dielectric layer of the MIM capacitor. The MIM capacitor may include a plurality of substantially “T-shaped” devices, which may extend three dimensionally, thus enabling greater capacitance per area as compared to conventional structures.

In a particular embodiment, a method of forming a metal-insulator-metal (MIM) capacitor includes removing, using a lithographic mask, a first portion of an optical planarization layer to expose a region in which the MIM capacitor is to be formed. A second portion of an insulating layer is formed on a first conductive layer that is formed on a plurality of trench surfaces within the region. The method further includes removing at least a third portion of the insulating layer according to a lift-off technique.

One particular advantage provided by at least one of the disclosed embodiments is that a MIM capacitor may be formed within a region defined by a single lithographic mask. Accordingly, by utilizing such a single-mask technique, costs and complexity may be reduced as compared to multi-mask fabrication techniques. In addition, the MIM capacitor may include “vertical” portions (namely, portions that extend substantially perpendicularly with respect to a semiconductor substrate surface). Accordingly, a width of the MIM capacitor may be less than conventional MIM capacitors while still achieving a high capacitance. Other aspects, advantages, and features of the present disclosure will become apparent after review of the entire application, including the following sections: Brief Description of the Drawings, Detailed Description, and the Claims.

### IV. BRIEF DESCRIPTION OF THE DRAWINGS

FIG. 1 is a diagram of a first illustrative diagram of a structure during at least one stage in a process of fabricating a semiconductor device that includes a metal-insulator-metal (MIM) capacitor;

FIG. 2 is a diagram of a second illustrative diagram of a structure during at least one stage in the process of fabricating a semiconductor device;

FIG. 3 is a diagram of a third illustrative diagram of a structure during at least one stage in the process of fabricating a semiconductor device;

FIG. 4 is a diagram of a fourth illustrative diagram of a structure during at least one stage in the process of fabricating a semiconductor device;

FIG. 5 is a diagram of a fifth illustrative diagram of a structure during at least one stage in the process of fabricating a semiconductor device;

FIG. 6 is a diagram of a sixth illustrative diagram of a structure during at least one stage in the process of fabricating a semiconductor device;

FIG. 7 is a diagram of a seventh illustrative diagram of a structure during at least one stage in the process of fabricating a semiconductor device;

FIG. 8 is a diagram of a eighth illustrative diagram of a structure during at least one stage in the process of fabricating a semiconductor device;

FIG. 9 is a diagram of a ninth illustrative diagram of a structure during at least one stage in the process of fabricating a semiconductor device;

FIG. 10 is a diagram of a tenth illustrative diagram of a structure during at least one stage in the process of fabricating a semiconductor device;

FIG. 11A is a flow chart of a particular illustrative embodiment of a method of forming a MIM capacitor according to a single-mask technique;

FIG. 11B is a flow chart of another particular illustrative embodiment of a method of forming a MIM capacitor according to a single-mask technique;

FIG. 12 is a block diagram of communication device including one or more MIM capacitors formed according to the method of FIG. 11A, the method of FIG. 11B, or a combination thereof; and

FIG. 13 is a data flow diagram of a particular illustrative embodiment of a manufacturing process to manufacture electronic devices that include a semiconductor device formed according to the method of FIG. 11A, the method of FIG. 11B, or a combination thereof.

### V. DETAILED DESCRIPTION

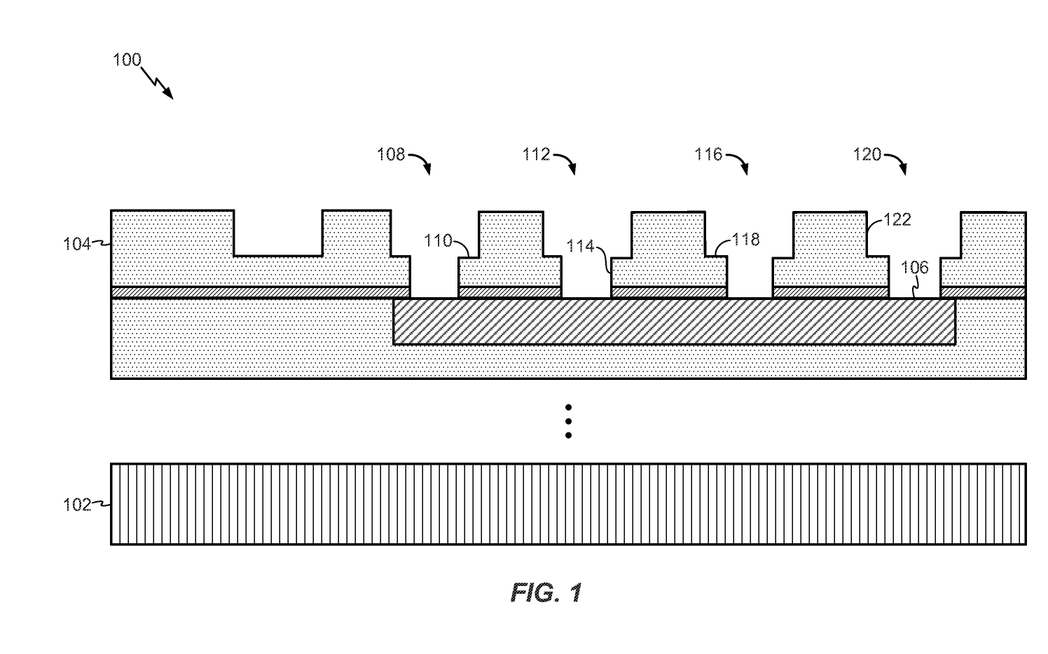

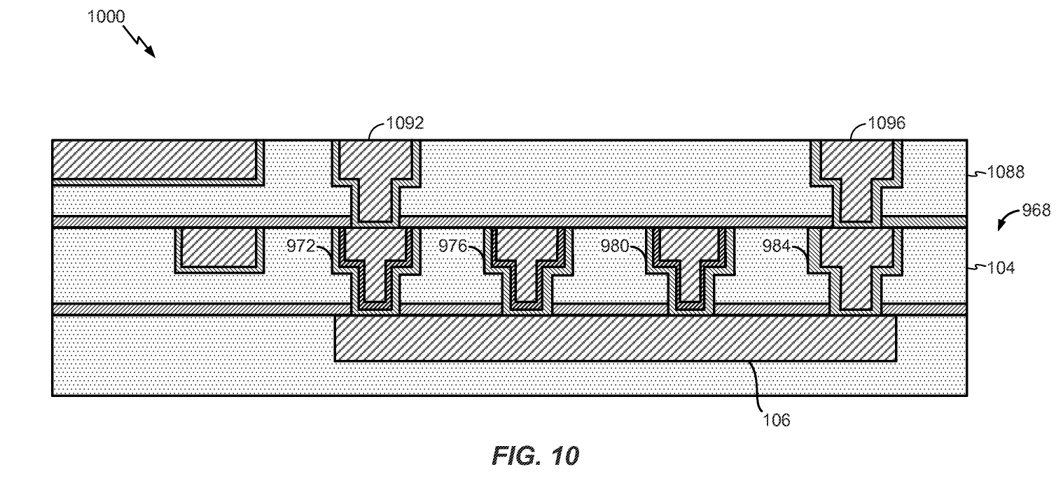

Referring to FIG. 1, a first illustrative diagram of a structure (e.g., a semiconductor structure) during at least one stage in a process of fabricating a semiconductor device (e.g., a process of fabricating an integrated circuit) is depicted and generally designated 100. As shown in FIG. 1, the structure 100 may include a semiconductor substrate 102 and an interconnect layer 104. The structure 100 may include additional layers, such as one or more layers between the semiconductor substrate 102 and the interconnect layer 104, additional layers above the interconnect layer 104, or a combination thereof. The interconnect layer 104 may be a metal interconnect layer of the structure 100, such as a metal interconnect layer formed during a back-end-of-line (BEOL) stage of fabricating the structure 100. The interconnect layer 104 may include a conductive (e.g., copper) structure 106 to couple bottom electrode portions of the MIM capacitor, as described further below with reference to FIG. 10.

In FIG. 1, a plurality of trenches has been formed (e.g. formed over the conductive structure 106). In the particular example of FIG. 1, a first trench 108, a second trench 112, a third trench 116, and a fourth trench 120 have been formed. Accordingly, a plurality trench surfaces have been formed on the interconnect layer 104. For example, in the particular embodiment of FIG. 1, a first trench surface 110, a second trench surface 114, a third trench surface 118, and a fourth trench surface 122 have been formed on the interconnect layer 104. According to alternate embodiments, the structure 100 may include a different number of trenches, a different number of trench surfaces, or a combination thereof, than those illustrated in FIG. 1. In the example of FIG. 1, each of the plurality of trenches defines a region that is substantially “T-shaped.”

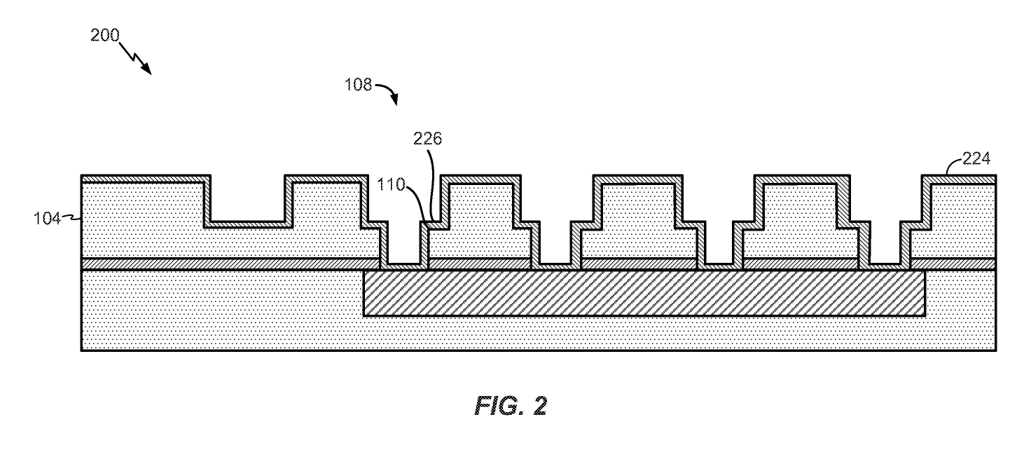

Referring to FIG. 2, a second illustrative diagram of a structure during at least one stage in the process of fabricating a semiconductor device is depicted and generally generated 200. In the example of FIG. 2, a first conductive layer 224 (e.g., a metal barrier layer) has been formed on the interconnect layer 104. As depicted in FIG. 2, the first conductive layer 224 includes portions formed within the plurality of trenches and on the plurality of trench surfaces described with reference to FIG. 1. For example, FIG. 2 depicts that a portion 226 of the first conductive layer 224 has been formed within the first trench 108 and on the first trench surface 110. The first conductive layer 224 may correspond to a first (e.g., “bottom”) electrode of a metal-insulator-metal (MIM) capacitor.

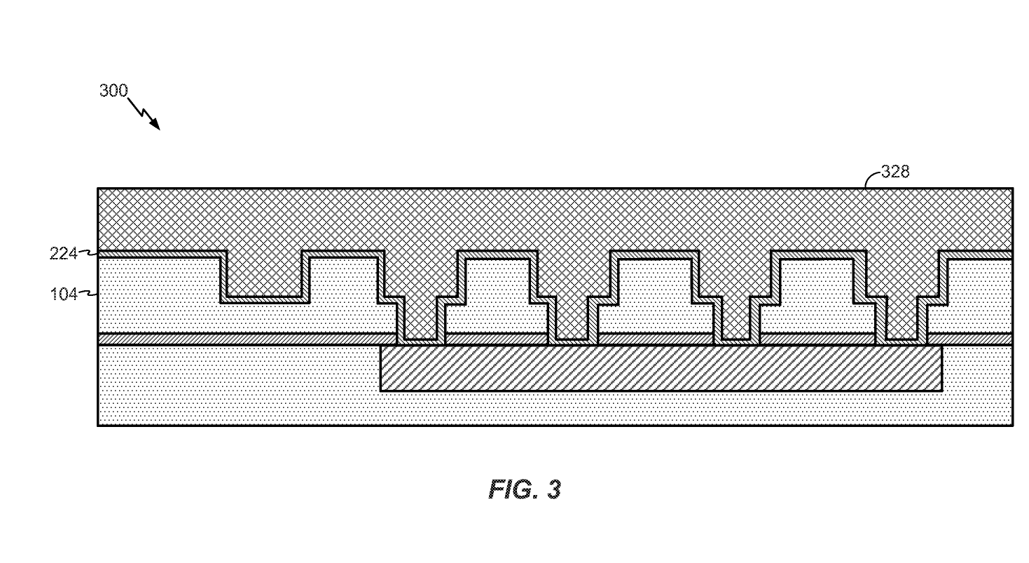

Referring to FIG. 3 a third illustrative diagram of a structure during at least one stage in the process of fabricating a semiconductor device is depicted and generally designated 300. FIG. 3 depicts that an optical planarization layer (OPL) 328 (or another sacrificial layer, or a combination thereof) has been formed. The optical planarization layer (OPL) 328 depicted in FIG. 3 is formed on the first conductive layer 224 and fills the plurality of trenches described with reference to FIG. 1.

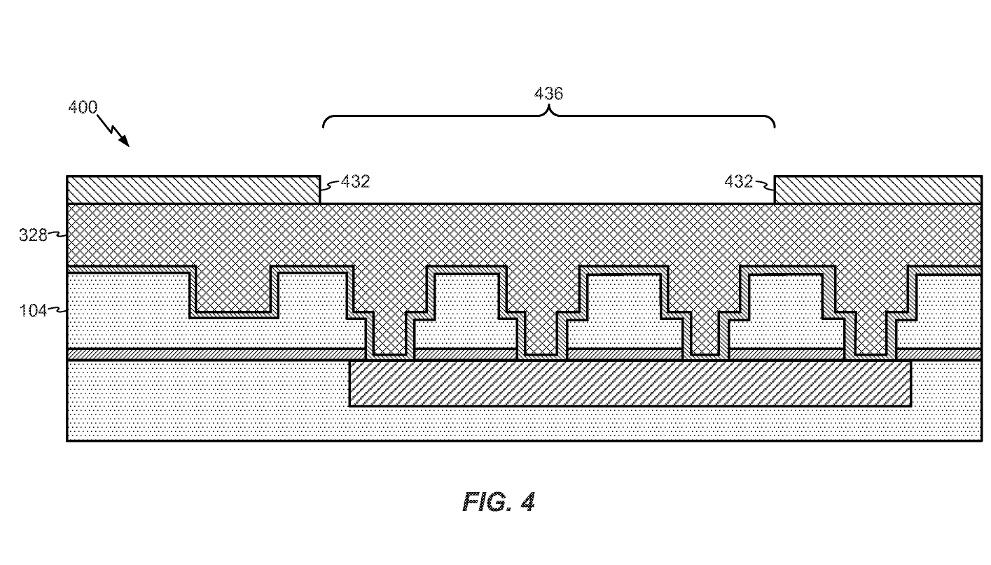

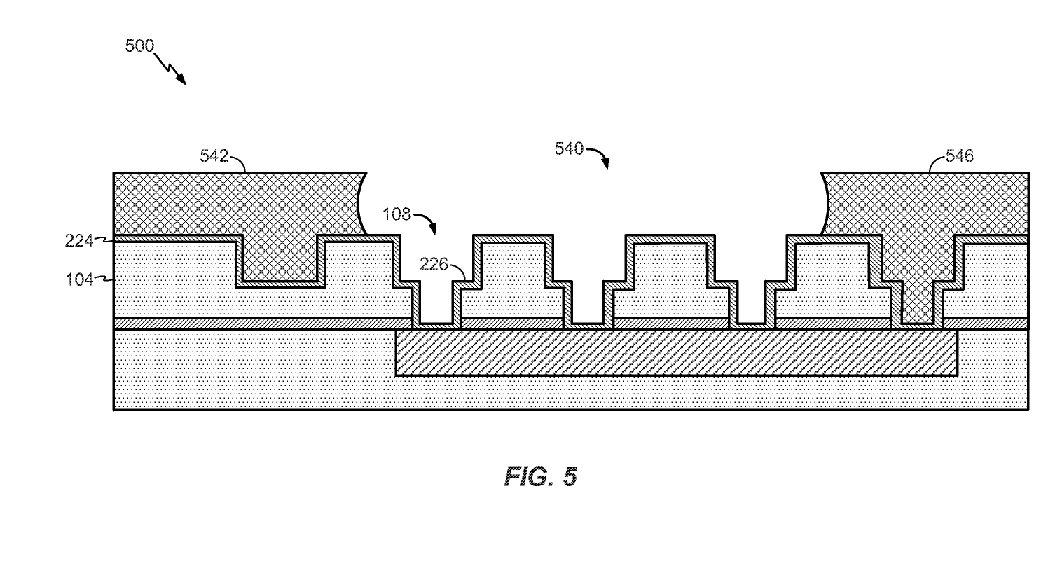

Referring to FIG. 4, a fourth illustrative diagram of a structure during at least one stage in the process of fabricating a semiconductor device is depicted and generally designated 400. FIG. 4 depicts that a lithographic mask 432 has been applied above the optical planarization layer 328. As depicted in FIG. 4, the lithographic mask 432 defines a region (depicted as a first portion 436 in FIG. 4) that may be removed (e.g., using a lithographic technique), as described further with reference to FIG. 5.

Referring to FIG. 5 a fifth illustrative diagram of a structure during at least one stage in the process of fabricating a semiconductor device is depicted and generally designated 500. FIG. 5 depicts that the lithographic mask 432 of FIG. 4 has been used to remove the first portion 436 defined by the lithographic mask 432 to expose a region 540. Removing the first portion 436 may include etching and cleaning various structures, such as the optical planarization layer 328. FIG. 5 further depicts that the lithographic mask 432 of FIG. 4 has been removed using a suitable technique and that a remainder of the optical planarization layer 328 (illustrated in the example of FIG. 5 as a second portion 542 and a third portion 546) may remain after removing the first portion 436.

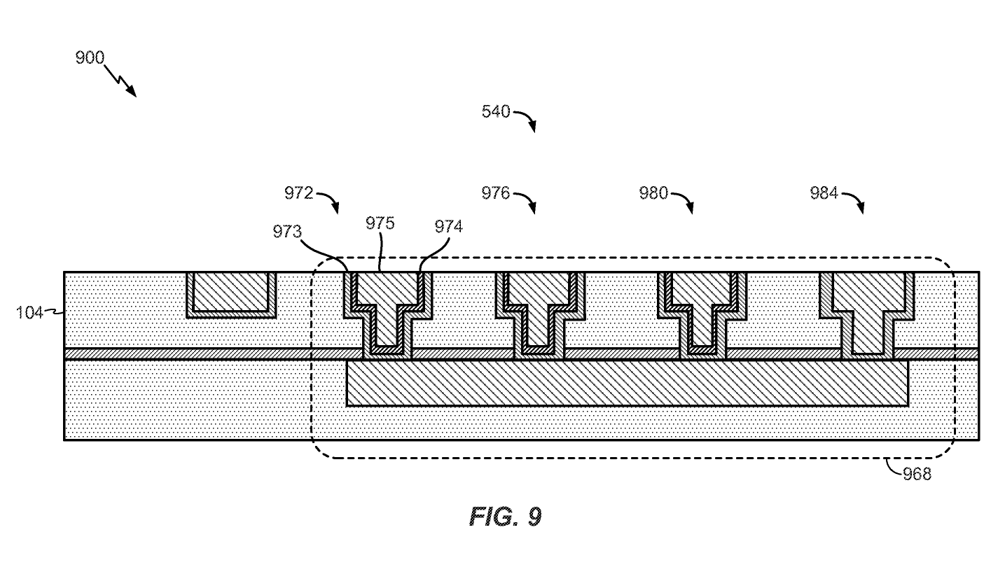

As illustrated in FIG. 5, exposing the region 540 exposes portions of the first conductive layer 224. For example, the portion 226 of the first conductive layer 224 formed within the first trench 108 described with reference to FIG. 2 has been exposed. Although FIG. 5 generally depicts that three trenches have been exposed by exposing the region 540, it should be appreciated that the example of FIG. 5 is illustrative and that alternate numbers of trenches may be exposed in accordance with alternate embodiments. For example, the number of trenches may depend on a particular capacitance (e.g. a MIM capacitor “density”) to be achieved for a particular application. That is, a number of substantially “T-shaped” structures may be varied (e.g., during a design phase) to achieve a particular capacitance, as described further below with reference to FIGS. 9 and 10.

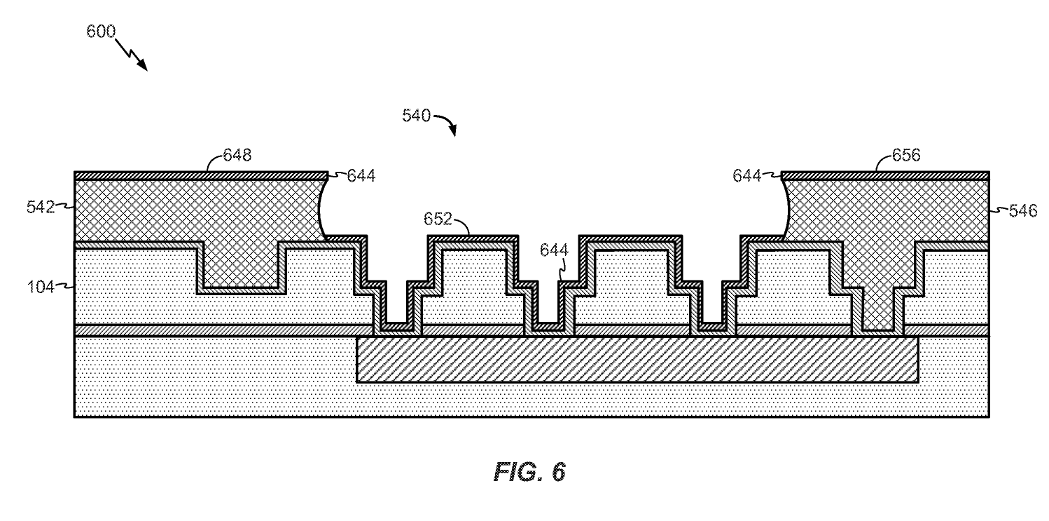

Referring to FIG. 6, a sixth illustrative diagram of a structure during at least one stage in the process of fabricating a semiconductor device is depicted and generally designated 600. In FIG. 6, an insulating layer 644 has been formed. The insulating layer 644 includes a first portion 652 formed within the region 540. The first portion 652 may be formed within one or more of the plurality of trenches described with reference to FIG. 1 and on one or more of the trench surfaces described with reference to FIG. 1. The insulating layer 644 may include one or more materials associated with a high dielectric constant (i.e., “high-K”). The first portion 652 may correspond to a dielectric layer of a metal-insulator-metal (MIM) capacitor.

In addition, the insulating layer 644 may further include a second portion 648 formed on the second portion 542. The insulating layer 644 may further include a third portion 656 formed on the third portion 546. The insulating layer 644 may include material associated with a high dielectric constant.

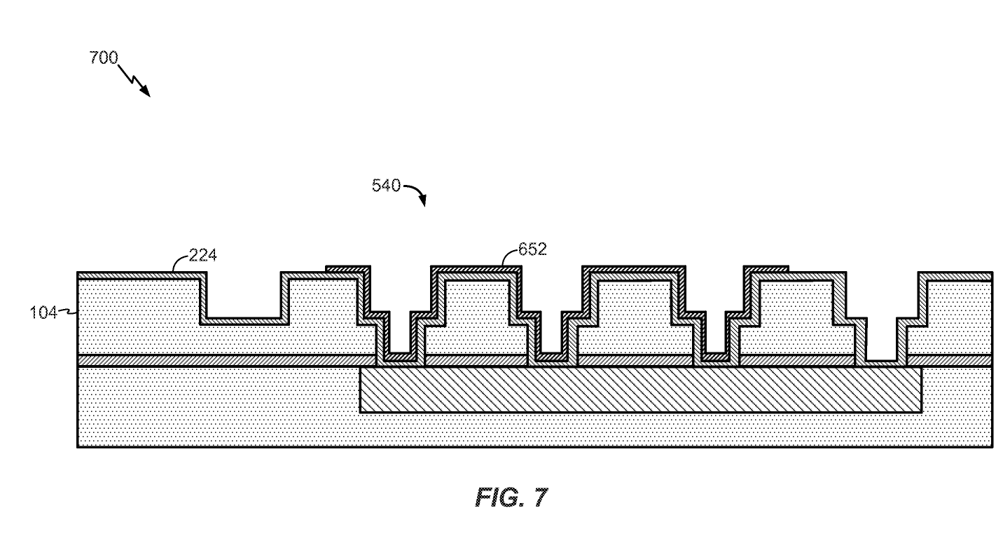

Referring to FIG. 7, a seventh illustrative diagram of a structure during at least one stage in the process of fabricating a semiconductor device is depicted and generally designated 700. In FIG. 7, the remainder of the optical planarization layer 328, the second portion 648 of the insulating layer 644, and the third portion 656 of the insulating layer 644 have been removed. In a particular illustrative embodiment, the remainder of the optical planarization layer 328, the second portion 648, and third portion 656 are removed according to a lift-off technique, such as a metal lift-off process. As shown in FIG. 7, the first portion 652 (or a portion thereof) remains after removing the remainder of the optical planarization layer 328, the second portion 648, and the third portion 656. As depicted in the example of FIG. 7, the first portion 652 is formed within the region 540 and on the first conductive layer 224.

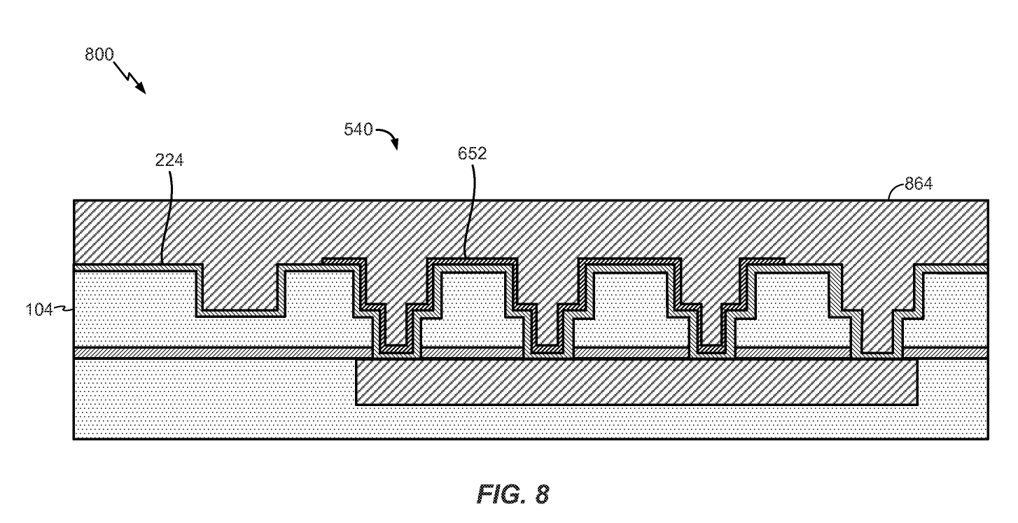

Referring to FIG. 8, an eighth illustrative diagram of a structure during at least one stage in the process of fabricating a semiconductor device is depicted and generally designated 800. FIG. 8 depicts that a second conductive layer 864 has been formed. As generally depicted in FIG. 8, the second conductive layer 864 may include at least one portion formed on the first conductive layer 224 and may further include at least another portion formed on the first portion 652 and within the region 540. The second conductive layer may include copper. In at least one embodiment, the second conductive layer 864 is formed using a copper seed deposition technique, an electroplating technique, or a combination thereof. The second conductive layer 864 may correspond to a second (e.g., “top”) electrode of a metal-insulator-metal (MIM) capacitor.

Referring to FIG. 9, a ninth illustrative diagram of a structure during at least one stage in the process of fabricating a semiconductor device is depicted and generally designated 900. In FIG. 9, a portion of the second conductive layer 864 has been removed. In at least one embodiment, the portion of the second conductive layer 864 is removed using a chemical-mechanical planarization (CMP) technique. By removing a portion of the second conductive layer 864, a metal insulator metal (MIM) capacitor 968 is formed. The MIM capacitor 968 is formed at least partially within the region 540 exposed using the lithographic mask 432 described with reference to FIGS. 4 and 5.

The MIM capacitor 968 of FIG. 9 includes a plurality of T-shaped devices. For example, the plurality of T-shaped devices may include a first T-shaped device 972, a second T-shaped device 976, a third T-shaped device 980, and a fourth T-shaped device 984. FIG. 9 depicts that one or more of the plurality of T-shaped devices (e.g., the first T-shaped device 972) include a portion 973 of the first conductive layer 224, a portion 974 of the first portion 652 of the insulating layer 644, and a portion 975 of the second conductive layer 864. The plurality of T-shaped devices may be electrically coupled via a connection (e.g., a metal connection) extending perpendicularly to (e.g., into, out of, or a combination thereof) the plane of FIG. 9 (i.e., three-dimensionally).

Referring to FIG. 10, a tenth illustrative diagram of a structure during at least one stage in the process of fabricating a semiconductor device is depicted and generally designated 1000. FIG. 10 depicts that a second interconnect layer 1088 (e.g., a second metal interconnect layer) has been formed above the interconnect layer 104 and above the MIM capacitor 968. The second interconnect layer 1088 includes a first via 1092 coupled to the first substantially T-shaped device 972 and further includes a second via 1096 coupled to the fourth substantially T-shaped device 984.

FIG. 10 further depicts that at least one substantially T-shaped device is coupled between the first substantially T-shaped device 972 and the fourth substantially T-shaped device 984. For example, in the particular example of FIG. 10, the second substantially T-shaped device 976 and the third substantially T-shaped device 980 are coupled between the first substantially T-shaped device 972 and the fourth substantially T-shaped device 984. Although FIGS. 9 and 10 generally depict that the MIM capacitor 968 includes four substantially T-shaped devices, alternate embodiments in accordance with the present disclosure may include a different number of substantially T-shaped devices. In at least one embodiment, the number of substantially T-shaped devices of the MIM capacitor 968 may be varied (e.g., during a design phase, during a layout phase, during another phase, or a combination thereof) to achieve a particular capacitance (or another characteristic) depending on the particular application for which the MIM capacitor 968 is to be used.

Further, as noted above with reference to FIG. 9, additional structures may extend three dimensionally with respect to the plane of FIG. 10. The additional structures may couple portions of the substantially T-shaped devices 972, 976, and 980 (e.g., portions formed by the second conductive layer 864, such as the portion 975) to the first via 1092. Further, the second via 1096 may be coupled to portions of the substantially T-shaped devices 972, 976, and 980 (e.g. portions formed by the first conductive layer 224, such as the portion 973) via the conductive structure 106, via additional three-dimensional structures not shown in FIG. 10, or a combination thereof. Accordingly, the MIM capacitor 968 may include a first conductive structure electrically connected to the first via 1092, a second conductive structure electrically connected to the second via 1096, and a dielectric structure (e.g., formed by portions of the insulating layer 644) that electrically isolates the first conductive structure with respect to the second conductive structure. In operation (e.g., after fabrication of and during operation of an integrated circuit that includes the MIM capacitor 968), the first via 1092 and the second via 1096 may be biased using respective voltages to apply a voltage difference between the first conductive structure and the second conductive structure.

It will be appreciated that the illustrative process of FIGS. 1-10 describes a single lithographic mask (e.g., the lithographic mask 432) that is used to form the MIM capacitor 968 within a region (e.g. the region 540) exposed by the lithographic mask. That is, a single mask is used to define the region 540 in which the MIM capacitor 968 is formed. Accordingly, costs may be reduced as compared to a multi-mask technique. In addition, because the MIM capacitor 968 includes “vertical” portions (namely, conductive portions that extend substantially perpendicularly with respect to the semiconductor substrate 102 of FIG. 1), a width of the MIM capacitor 968 may be less than conventional MIM capacitors (e.g., “flat” or “plate” MIM capacitors) while still achieving a high capacitance for the MIM capacitor 968, which may enable a higher “density” associated with the MIM capacitor 968. Further, it should be appreciated that the structures of the MIM capacitor 968 may extend three-dimensionally (i.e., perpendicularly with respect to the plane of FIGS. 1-10), further adding area for the layers of the MIM capacitor 968, which may enable a high capacitance for the MIM capacitor 968.

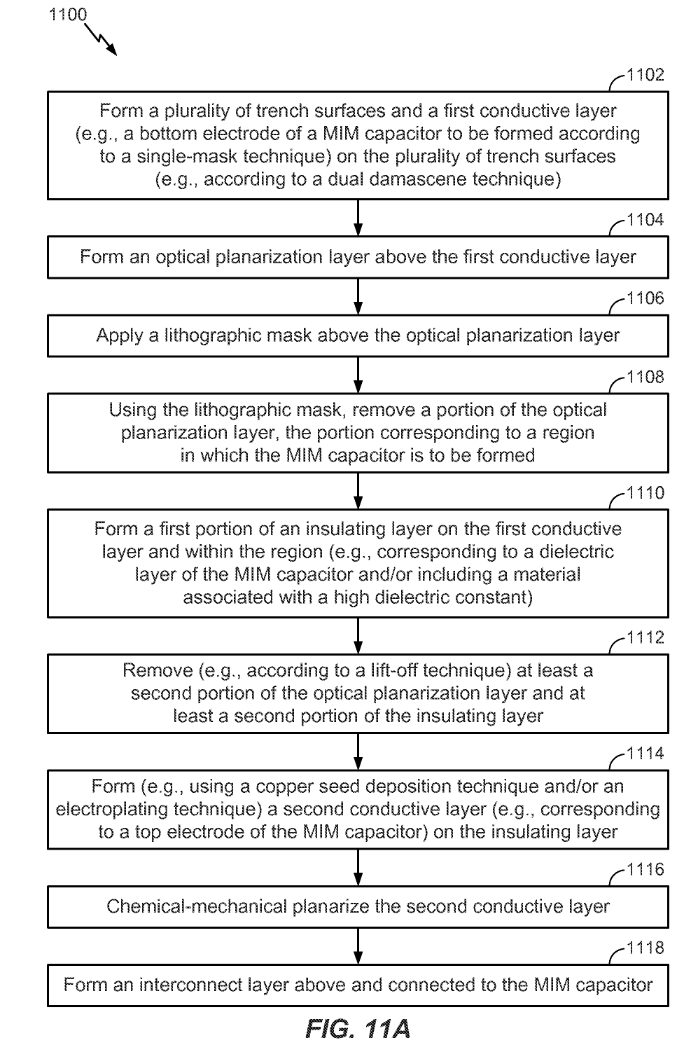

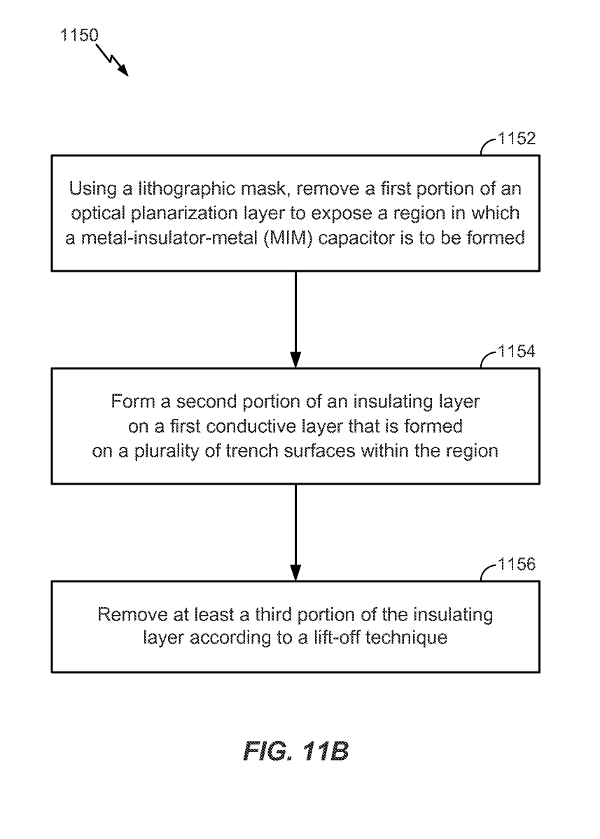

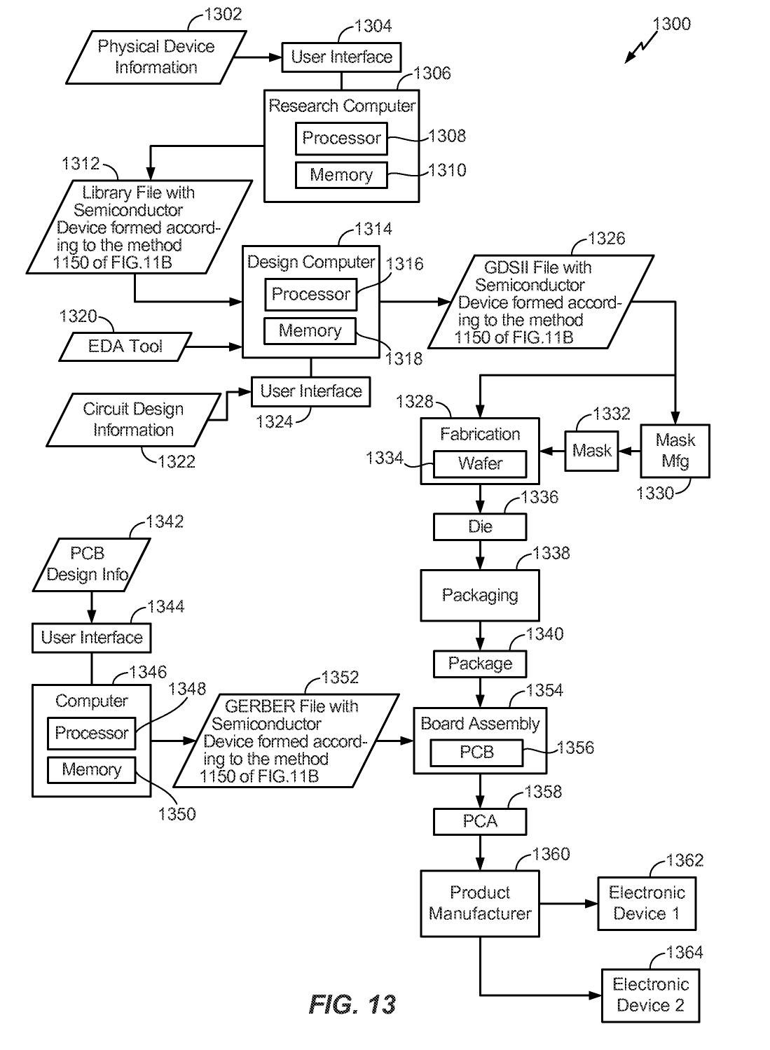

Referring to FIG. 11A, a flow chart of a particular illustrative embodiment of a method of forming a metal insulator metal (MIM) capacitor (e.g., the MIM capacitor 968) according to a single-mask technique is depicted and generally designated 1100. One or more operations of the method 1100 may be initiated by a processor integrated into an electronic device, such as equipment of a semiconductor manufacturing plant (e.g., a “fab”), as described further with reference to FIG. 13.

The method 1100 includes forming a plurality of trench surfaces and a first conductive layer on the plurality of trench surfaces (e.g., according to a dual damascene technique), at 1102. For example, as described with reference to FIG. 2, one or more portions of the first conductive layer 224 may be formed within the first trench 108 and on the first trench surface 110. The first conductive layer may correspond to a bottom electrode of the MIM capacitor.

At 1104, an optical planarization layer (e.g. the optical planarization layer 328) is formed above the first conductive layer. A lithographic mask (e.g., the lithographic mask 432) is applied above the optical planarization layer, at 1106. Using the lithographic mask, a portion (e.g., the first portion 436) of the optical planarization layer is removed, at 1108. The portion corresponds to an area in which the MIM capacitor is to be formed.

The method 1100 further includes forming a first portion (e.g., the first portion 652) of an insulating layer on the first conductive layer and within the region, at 1110. The first portion may correspond to a dielectric layer of the MIM capacitor, may include a material associated with a high dielectric constant, or a combination thereof.

At 1112, at least a second portion of the optical planarization layer (e.g. the second portion 542, the third portion 546, or a combination thereof) and at least a second portion (e.g., the second portion 648, the third portion 656, or a combination thereof) of the insulating layer are removed. The second portion of the optical planarization layer and the second portion of the insulating layer may be removed according to a lift-off technique, such as a metal lift-off process.

At 1114, a second conductive layer (e.g., the second conductive layer 864) is formed on the insulating layer. The second conductive layer may be formed using a copper seed deposition technique, an electroplating technique, or a combination thereof. The second conductive layer may correspond to a top electrode of the MIM capacitor.

The method 1100 further includes chemical-mechanical planarizing the second conductive layer, at 1116. At 1118, an interconnect layer (e.g., the second interconnect layer 1088) is formed above and connected to the MIM capacitor. At least a portion of the MIM capacitor is formed within the region exposed using the lithographic mask.

It will be appreciated that forming at least a portion of the MIM capacitor within the region exposed using the single lithographic mask of FIG. 11A enables reduced cost and complexity as compared to fabrication of a MIM capacitor using a multiple-mask technique. In at least one embodiment, forming portions of the MIM capacitor on the plurality of trench surfaces may enable substantially “T-shaped” structures and may avoid multiple “flat” structures each associated with a respective mask, thereby decreasing cost and complexity of fabrication of the MIM capacitor.

Referring to FIG. 11B, a flow chart of a particular illustrative embodiment of a method of forming a metal insulator metal (MIM) capacitor (e.g., the MIM capacitor 968) according to a single-mask technique is depicted and generally designated 1150. One or more operations of the method 1150 may be initiated by a processor integrated into an electronic device, such as equipment of a semiconductor manufacturing plant (e.g., a “fab”), as described further with reference to FIG. 13.

The method 1150 includes removing a first portion (e.g., the first portion 436) of an optical planarization layer using a lithographic mask to expose a region in which the MIM capacitor is to be formed, at 1152. The optical planarization layer may correspond to the optical planarization layer 328. The lithographic mask may correspond to the lithographic mask 432. The region in which the MIM capacitor is to be formed may correspond to the region 540.

The method 1150 further includes forming a second portion (e.g., the first portion 652) of an insulating layer (e.g., the insulating layer 644) on a first conductive layer (e.g., the first conductive layer 224) that is formed on a plurality of trench surfaces (e.g., one or more of the trench surfaces 110, 114, 118, 122) within the region, at 1154. For example, as described with reference to FIG. 2, one or more portions of the first conductive layer 224 may be formed within the first trench 108 and on the first trench surface 110. The first conductive layer may correspond to a bottom electrode of the MIM capacitor. The second portion of the insulating layer may correspond to a dielectric layer of the MIM capacitor, may include a material associated with a high dielectric constant, or a combination thereof.

At 1156, at least a third portion of the insulating layer is removed according to a lift-off technique. Removing at least the third portion of the insulating layer may include removing the second portion 648, the third portion 656, or a combination thereof.

One or more of the operations described with reference to the method 1100 of FIG. 11A, the method 1150 of FIG. 11B, or a combination thereof, may be initiated by a field-programmable gate array (FPGA) device, an application-specific integrated circuit (ASIC), a processing unit such as a central processing unit (CPU), a digital signal processor (DSP), a controller, another hardware device, a firmware device, or any combination thereof. As an example, the method 1100 of FIG. 11A, the method 1150 of FIG. 11B, or a combination thereof, can be initiated by semiconductor fabrication equipment, such as a processor that executes instructions stored at a memory (e.g., a non-transitory computer-readable medium), as described further with reference to FIG. 13.

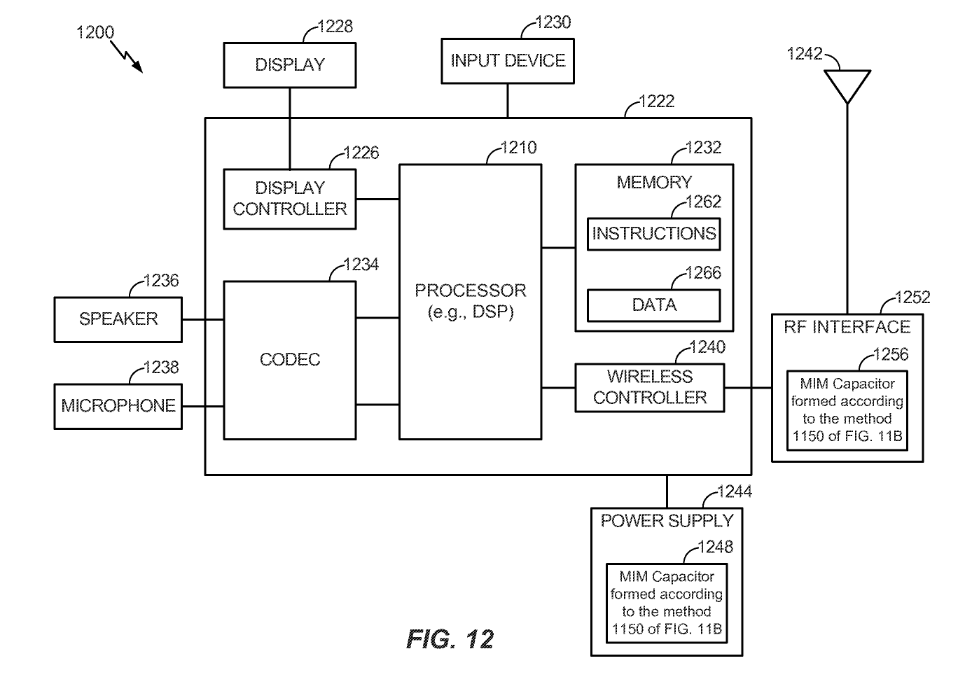

Referring to FIG. 12, a block diagram of a particular illustrative embodiment of a mobile device is depicted and generally designated 1200. The mobile device 1200 may include a processor 1210, such as a digital signal processor (DSP). The processor 1210 may be coupled to a memory 1232 (e.g., a non-transitory computer-readable medium). The memory 1232 may store instructions 1262 executable by the processor 1210. The memory 1232 may store data 1266 accessible to the processor 1210.

FIG. 12 also shows a display controller 1226 that is coupled to the processor 1210 and to a display 1228. A coder/decoder (CODEC) 1234 can also be coupled to the processor 1210. A speaker 1236 and a microphone 1238 can be coupled to the CODEC 1234. FIG. 12 also indicates that a wireless controller 1240 can be coupled to the processor 1210 and can be further coupled to a wireless antenna 1242 via a radio frequency (RF) interface 1252.

In a particular embodiment, the processor 1210, the display controller 1226, the memory 1232, the CODEC 1234, and the wireless controller 1240 are included in a system-in-package or system-on-chip device 1222. An input device 1230 and a power supply 1244 may be coupled to the system-on-chip device 1222. Moreover, in a particular embodiment, and as illustrated in FIG. 12, the display 1228, the input device 1230, the speaker 1236, the microphone 1238, the wireless antenna 1242, and the power supply 1244 are external to the system-on-chip device 1222. However, each of the display 1228, the input device 1230, the speaker 1236, the microphone 1238, the wireless antenna 1242, and the power supply 1244 can be coupled to a component of the system-on-chip device 1222, such as an interface or a controller.

The mobile device 1200 includes at least one MIM capacitor formed according to a single-mask technique, such as according to the method 1100 of FIG. 11A, the method 1150 of FIG. 11B, or a combination thereof. For example, as depicted in FIG. 12, the RF interface 1252 may include a MIM capacitor 1256 formed according to the method 1100 of FIG. 11A, the method 1150 of FIG. 11B, or a combination thereof. As another example, FIG. 12 illustrates that the power supply 1244 may include a MIM capacitor 1248 formed according to the method 1100 of FIG. 11A, the method 1150 of FIG. 11B, or a combination thereof. As another example, the system-on-chip device 1222, one or more components of the system-on-chip device 1222, or a combination thereof, may include a MIM capacitor formed according to the method 1100 of FIG. 11A, the method 1150 of FIG. 11B, or a combination thereof (not shown in FIG. 12).

The foregoing disclosed devices and functionalities may be designed and configured into computer files (e.g. RTL, GDSII, GERBER, etc.) stored on computer-readable media. Some or all such files may be provided to fabrication handlers to fabricate devices based on such files. Resulting products include semiconductor wafers that are then cut into semiconductor dies and packaged into semiconductor chips. The semiconductor chips are then integrated into electronic devices, as described further with reference to FIG. 13.

Referring to FIG. 13, a particular illustrative embodiment of an electronic device manufacturing process is depicted and generally designated 1300. In FIG. 13, physical device information 1302 is received at the manufacturing process 1300, such as at a research computer 1306. The physical device information 1302 may include design information representing at least one physical property of a semiconductor device, such as a MIM capacitor formed according to a single-mask technique (e.g., according to the method 1100 of FIG. 11A, the method 1150 of FIG. 11B, or a combination thereof). For example, the physical device information 1302 may include physical parameters, material characteristics, and structure information that is entered via a user interface 1304 coupled to the research computer 1306. The research computer 1306 includes a processor 1308, such as one or more processing cores, coupled to a computer-readable medium such as a memory 1310. The memory 1310 may store computer-readable instructions that are executable to cause the processor 1308 to transform the physical device information 1302 to comply with a file format and to generate a library file 1312.

In a particular embodiment, the library file 1312 includes at least one data file including the transformed design information. For example, the library file 1312 may include a library of semiconductor devices, including a semiconductor device formed according to the method 1100 of FIG. 11A, the method 1150 of FIG. 11B, or a combination thereof, provided for use with an electronic design automation (EDA) tool 1320.

The library file 1312 may be used in conjunction with the EDA tool 1320 at a design computer 1314 including a processor 1316, such as one or more processing cores, coupled to a memory 1318. The EDA tool 1320 may be stored as processor executable instructions at the memory 1318 to enable a user of the design computer 1314 to design a circuit including the semiconductor device formed according to the method 1100 of FIG. 11A, the method 1150 of FIG. 11B, or a combination thereof, using the library file 1312. For example, a user of the design computer 1314 may enter circuit design information 1322 via a user interface 1324 coupled to the design computer 1314. The circuit design information 1322 may include design information representing at least one physical property of a semiconductor device, such as a semiconductor device formed according to the method 1100 of FIG. 11A, the method 1150 of FIG. 11B, or a combination thereof. To illustrate, the circuit design property may include identification of particular circuits and relationships to other elements in a circuit design, positioning information, feature size information, interconnection information, or other information representing a physical property of a semiconductor device.

The design computer 1314 may be configured to transform the design information, including the circuit design information 1322, to comply with a file format. To illustrate, the file formation may include a database binary file format representing planar geometric shapes, text labels, and other information about a circuit layout in a hierarchical format, such as a Graphic Data System (GDSII) file format. The design computer 1314 may be configured to generate a data file including the transformed design information, such as a GDSII file 1326 that includes information describing a semiconductor device formed according to the method 1100 of FIG. 11A, the method 1150 of FIG. 11B, or a combination thereof, in addition to other circuits or information. To illustrate, the data file may include information corresponding to a system-on-chip (SOC) that includes a semiconductor device formed according to the method 1100 of FIG. 11A, the method 1150 of FIG. 11B, or a combination thereof, and that also includes additional electronic circuits and components within the SOC.

The GDSII file 1326 may be received at a fabrication process 1328 to manufacture a semiconductor device according to the method 1100 of FIG. 11A, the method 1150 of FIG. 11B, or a combination thereof, and according to transformed information in the GDSII file 1326. For example, a device manufacture process may include providing the GDSII file 1326 to a mask manufacturer 1330 to create one or more masks, such as masks to be used with photolithography processing, illustrated in FIG. 13 as a representative mask 1332. In at least one embodiment, the mask 1332 includes the lithographic mask 432. Accordingly to further embodiments, the lithographic mask 432 may be generated using alternate techniques. The mask 1332 may be used during the fabrication process to generate one or more wafers 1334, which may be tested and separated into dies, such as a representative die 1336. The die 1336 includes a circuit including a semiconductor device formed according to the method 1100 of FIG. 11A, the method 1150 of FIG. 11B, or a combination thereof.

In conjunction with the described embodiments, a non-transitory computer-readable medium stores instructions executable by a computer to initiate the method 1100 of FIG. 11A, the method 1150 of FIG. 11B, or a combination thereof. For example, equipment of a semiconductor manufacturing plant may include the computer and the memory and may initiate the method 1100 of FIG. 11A, the method 1150 of FIG. 11B, or a combination thereof, such as in connection with the fabrication process 1328 and using the GSDII file 1326.

The die 1336 may be provided to a packaging process 1338 where the die 1336 is incorporated into a representative package 1340. For example, the package 1340 may include the single die 1336 or multiple dies, such as a system-in-package (SiP) arrangement. The package 1340 may be configured to conform to one or more standards or specifications, such as Joint Electron Device Engineering Council (JEDEC) standards.

Information regarding the package 1340 may be distributed to various product designers, such as via a component library stored at a computer 1346. The computer 1346 may include a processor 1348, such as one or more processing cores, coupled to a memory 1350. A printed circuit board (PCB) tool may be stored as processor executable instructions at the memory 1350 to process PCB design information 1342 received from a user of the computer 1346 via a user interface 1344. The PCB design information 1342 may include physical positioning information of a packaged semiconductor device on a circuit board, the packaged semiconductor device corresponding to the package 1340 including a semiconductor device formed according to the method 1100 of FIG. 11A, the method 1150 of FIG. 11B, or a combination thereof.

The computer 1346 may be configured to transform the PCB design information 1342 to generate a data file, such as a GERBER file 1352 with data that includes physical positioning information of a packaged semiconductor device on a circuit board, as well as layout of electrical connections such as traces and vias, where the packaged semiconductor device corresponds to the package 1340 including a semiconductor device formed according to the method 1100 of FIG. 11A, the method 1150 of FIG. 11B, or a combination thereof. In other embodiments, the data file generated by the transformed PCB design information may have a format other than a GERBER format.

The GERBER file 1352 may be received at a board assembly process 1354 and used to create PCBs, such as a representative PCB 1356, manufactured in accordance with the design information stored within the GERBER file 1352. For example, the GERBER file 1352 may be uploaded to one or more machines to perform various steps of a PCB production process. The PCB 1356 may be populated with electronic components including the package 1340 to form a representative printed circuit assembly (PCA) 1358.

The PCA 1358 may be received at a product manufacture process 1360 and integrated into one or more electronic devices, such as a first representative electronic device 1362 and a second representative electronic device 1364. As an illustrative, non-limiting example, the first representative electronic device 1362, the second representative electronic device 1364, or both, may be selected from the group of a set top box, a music player, a video player, an entertainment unit, a navigation device, a communications device, a personal digital assistant (PDA), a fixed location data unit, and a computer, into which a semiconductor device formed according to the method 1100 of FIG. 11A, the method 1150 of FIG. 11B, or a combination thereof, is integrated. As another illustrative, non-limiting example, one or more of the electronic devices 1362 and 1364 may be remote units such as mobile phones, hand-held personal communication systems (PCS) units, portable data units such as personal data assistants, global positioning system (GPS) enabled devices, navigation devices, fixed location data units such as meter reading equipment, or any other device that stores or retrieves data or computer instructions, or any combination thereof. Although FIG. 13 illustrates remote units according to teachings of the disclosure, the disclosure is not limited to these illustrated units. Embodiments of the disclosure may be suitably employed in any device which includes active integrated circuitry including memory and on-chip circuitry.

A device that includes a semiconductor device formed according to the method 1100 of FIG. 11A, the method 1150 of FIG. 11B, or a combination thereof, may be fabricated, processed, and incorporated into an electronic device, as described in the illustrative process 1300. One or more aspects of the embodiments disclosed with respect to FIGS. 1-13 may be included at various processing stages, such as within the library file 1312, the GDSII file 1326, and the GERBER file 1352, as well as stored at the memory 1310 of the research computer 1306, the memory 1318 of the design computer 1314, the memory 1350 of the computer 1346, the memory of one or more other computers or processors (not shown) used at the various stages, such as at the board assembly process 1354, and also incorporated into one or more other physical embodiments such as the mask 1332, the die 1336, the package 1340, the PCA 1358, other products such as prototype circuits or devices (not shown), or any combination thereof. Although various representative stages are depicted with reference to FIGS. 1-13, in other embodiments fewer stages may be used or additional stages may be included. Similarly, the process 1300 of FIG. 13 may be performed by a single entity or by one or more entities performing various stages of the process 1300.

In conjunction with the described embodiments, an apparatus is disclosed that includes a first semiconductor device formed according to the method 1100 of FIG. 11A, the method 1150 of FIG. 11B, or a combination thereof. The first semiconductor device may include the MIM capacitor 1256, the MIM capacitor 1248, or a combination thereof. The apparatus further includes means for electrically coupling the first semiconductor device to at least a second semiconductor device (e.g., the PCB 1356).

As used herein, “substantially T-shaped” may refer to structures that those of skill in the art would recognize as T-shaped or relatively T-shaped. For example, “substantially T-shaped” may refer to structures that include a first (e.g. top) portion having a rectangular (e.g., square) shape and that is coupled to a second (e.g., bottom) portion having a rectangular (e.g. square) shape, where the first portion has a width that is greater than a width of the second portion. Those of skill in the art will recognize that additional substantially T-shaped structures are within the scope of the present disclosure.

Those of skill would further appreciate that the various illustrative logical blocks, configurations, modules, circuits, and algorithm steps described in connection with the embodiments disclosed herein may be implemented as electronic hardware, computer software executed by a processor, or combinations of both. Various illustrative components, blocks, configurations, modules, circuits, and steps have been described above generally in terms of their functionality. Whether such functionality is implemented as hardware or processor executable instructions depends upon the particular application and design constraints imposed on the overall system. Skilled artisans may implement the described functionality in varying ways for each particular application, but such implementation decisions should not be interpreted as causing a departure from the scope of the present disclosure.

The steps of a method or algorithm described in connection with the embodiments disclosed herein may be embodied directly in hardware, in a software module executed by a processor, or in a combination of the two. A software module may reside in random access memory (RAM), flash memory, read-only memory (ROM), programmable read-only memory (PROM), erasable programmable read-only memory (EPROM), electrically erasable programmable read-only memory (EEPROM), registers, hard disk, a removable disk, a compact disc read-only memory (CD-ROM), or any other form of non-transient storage medium known in the art. An exemplary storage medium is coupled to the processor such that the processor can read information from, and write information to, the storage medium. In the alternative, the storage medium may be integral to the processor. The processor and the storage medium may reside in an application-specific integrated circuit (ASIC). The ASIC may reside in a computing device or a user terminal. In the alternative, the processor and the storage medium may reside as discrete components in a computing device or user terminal.

The previous description of the disclosed embodiments is provided to enable a person skilled in the art to make or use the disclosed embodiments. Various modifications to these embodiments will be readily apparent to those skilled in the art, and the principles defined herein may be applied to other embodiments without departing from the scope of the disclosure. Thus, the present disclosure is not intended to be limited to the embodiments shown herein but is to be accorded the widest scope possible consistent with the principles and novel features as defined by the following claims.

What is claimed is:

1. A method of forming a metal-insulator-metal (MIM) capacitor, the method comprising:
using a lithographic mask, removing a first portion of an optical planarization layer to expose a region in which the MIM capacitor is to be formed;
forming a second portion of an insulating layer on a first conductive layer that is formed on a plurality of trench surfaces within the region; and
removing at least a third portion of the insulating layer according to a lift-off technique.

2. The method of claim 1, wherein the MIM capacitor is formed according to a single-mask technique that utilizes the lithographic mask.

3. The method of claim 1, wherein the first conductive layer corresponds to a bottom electrode of the MIM capacitor, and further comprising:
forming a second conductive layer on the insulating layer, and
chemical-mechanical planarizing the second conductive layer.

4. The method of claim 3, wherein the second conductive layer is formed using a copper seed deposition technique, an electroplating technique, or a combination thereof.

5. The method of claim 1, further comprising:
forming the plurality of trench surfaces and the first conductive layer on the plurality of trench surfaces according to a dual damascene technique;
forming the optical planarization layer on the first conductive layer; and
applying the lithographic mask on at least a fourth portion of the optical planarization layer.

6. The method of claim 1, wherein the insulating layer comprises material associated with a high dielectric constant.

7. The method of claim 1, wherein the third portion of the insulating layer and a fourth portion of the optical planarization layer are removed according to a metal lift-off process.

8. The method of claim 1, further comprising forming an interconnect layer above and connected to the MIM capacitor, wherein the interconnect layer includes a first via coupled to a first substantially T-shaped device and further includes a second via coupled to a second substantially T-shaped device, wherein at least a third substantially T-shaped device is coupled between the first substantially T-shaped device and the second substantially T-shaped device.

9. The method of claim 1, wherein removing a first portion, forming the second portion, and removing the third portion are initiated by a processor integrated into an electronic device.

10. An apparatus comprising:
a semiconductor device formed according to the method of claim 1.

11. The apparatus of claim 10, integrated in at least one semiconductor die.

12. The apparatus of claim 10, further comprising a device selected from the group of a set top box, a music player, a video player, an entertainment unit, a navigation device, a communications device, a personal digital assistant (PDA), a fixed location data unit, and a computer, into which the semiconductor device is integrated.

13. A method of forming a metal-insulator-metal (MIM) capacitor, the method comprising:
a first step for removing, using a lithographic mask, a first portion of an optical planarization layer to expose a region in which the MIM capacitor is to be formed;
a second step for forming a second portion of an insulating layer on a first conductive layer that is formed on a plurality of trench surfaces within the region; and
a third step for removing at least a third portion of the insulating layer according to a lift-off technique.

14. The method of claim 13, wherein the first step, the second step, and the third step are initiated by a processor integrated into an electronic device.

15. A method comprising:
receiving a data file including design information corresponding to a semiconductor device; and
fabricating the semiconductor device according to the design information, wherein the semiconductor device includes a MIM capacitor formed according to the method of claim 1.

16. The method of claim 15, wherein the data file has a GDSII format.

17. A method comprising:
receiving design information including physical positioning information of a packaged semiconductor device on a circuit board, the packaged semiconductor device including a MIM capacitor formed according to the method of claim 1; and
transforming the design information to generate a data file.

18. The method of claim 17, wherein the data file has a GERBER format.

19. A method comprising:
receiving a data file including design information including physical positioning information of a packaged semiconductor device on a circuit board; and
manufacturing the circuit board, the circuit board configured to receive the packaged semiconductor device according to the design information, wherein the packaged semiconductor device includes a MIM capacitor formed according to the method of claim 1.

20. The method of claim 19, wherein the data file has a GERBER format.

21. The method of claim 19, further comprising integrating the circuit board into a device selected from the group of a set top box, a music player, a video player, an entertainment unit, a navigation device, a communications device, a personal digital assistant (PDA), a fixed location data unit, and a computer.

22. A non-transitory computer-readable medium storing instructions executable by a computer to perform the method of claim 1.

23. An apparatus comprising:
a first semiconductor device that includes a MIM capacitor formed according to the method of claim 1; and
means for electrically coupling the first semiconductor device to at least a second semiconductor device.

24. The apparatus of claim 23, wherein the means for electrically coupling the first semiconductor device to at least the second semiconductor device comprises a printed circuit board (PCB).
